(19) United States
(12) Patent Application Publication
(10) Pub. No.: US 2026/0029480 A1
(43) Pub. Date: Jan. 29, 2026

(54) METHOD AND SYSTEM FOR STATE ESTIMATION BASED ON IMPEDANCE FEATURES

(71) Applicant: TEXAS INSTRUMENTS INCORPORATED, Dallas, TX (US)

(72) Inventors: Venkatesh Kabra, Richardson, TX (US); David P. Magee, Allen, TX (US)

(21) Appl. No.: 19/092,141

(22) Filed: Mar. 27, 2025

Related U.S. Application Data
(60) Provisional application No. 63/676,575, filed on Jul. 29, 2024.

(51) Int. Cl. G01R 31/389; G01R 31/3842

(52) U.S. Cl. CPC G01R 31/389; G01R 31/3842

(57) ABSTRACT

A method comprises obtaining a set of impedance values of a first device under test (DUT) across a range of excitation frequencies for a given set of values of a particular state. The method further comprises determining a relationship between the given set of values of the state and the set of impedance values. The method further comprises storing data representing the relationship in a memory, receiving a voltage signal and a current signal from a second DUT, determining an impedance of the second DUT responsive to receiving the voltage and current signals, and determining a value of the state of the second DUT based on the impedance and the data.

### RELATED APPLICATION

This application claims priority to U.S. Provisional Application No. 63/676,575, filed Jul. 29, 2024, entitled “State Estimation for Batteries Based on Cell Impedance Features,” which is hereby incorporated by reference.

### BACKGROUND

Battery cells, such as lithium-ion (Li-ion) battery (LIB) cells, have been used in portable electronics and consumer products for the past twenty years because of their high energy density and memoryless recharging capabilities. Recent developments using new chemical compositions have further increased the energy density, which expanded the application space to include electric vehicles (EV) and hybrid electric vehicles (HEV). With these new automotive applications comes more stringent requirements for safety and reliability.

LIBs have been used for various applications such as electric vehicles EVs, Grid scale energy solutions (GSES), electric vertical take-off and landing (eVTOLs) aircrafts etc. These solutions are enabled by the high energy density and hysteresis free charging behavior of the LIBs. The constant evolution of the battery chemistries catering to ever growing applications makes it a challenge to develop a scalable solution for determining various states of the battery cells, such as temperature, state of charge (SoC), and state of health (SoH).

### SUMMARY

In one example, a method comprises obtaining a set of impedance values of a first device under test (DUT) across a range of excitation frequencies for a given set of values of a particular state. The method further comprises determining a relationship between the given set of values of the state and the set of impedance values. The method further comprises storing data representing the relationship in a memory, receiving a voltage signal and a current signal from a second DUT, determining an impedance of the second DUT responsive to receiving the voltage and current signals, and determining a value of the state of the second DUT based on the impedance and the data.

In one example, a method comprises obtaining a set of voltage signals and a set of current signals from a device under test (DUT) over a range of excitation frequencies across a set of values of a particular state. The method further comprises determining a set of impedance values of the DUT based on the set of voltage signals and the set of current signals, determining a relationship between the set of values of the state and the set of impedance values, and storing data representing the relationship in a memory.

In one example, an apparatus comprises a memory configurable to store a first data representing a relationship between a set of values of a state of a first device and a first impedance of the first device across a frequency range. The apparatus further comprises a processing circuit having inputs coupled to the memory and an output, the processing circuit configurable to determine a second impedance of a second device across the frequency range, receive the first data from the memory, receive at least part of the first data responsive to determining the second impedance, and responsive to receiving the at least part of the first data, determine a state of the second device.

In one example, a non-transitory computer readable medium storing instructions that, when executed by a processor circuitry, cause the processor circuitry to obtain a set of impedance values of a first device under test (DUT) across a range of excitation frequencies for a set of values of a particular state, determine a relationship between the set of values of the state and the set of impedance values, store data representing the relationship in a memory, receive a voltage signal and a current signal from a second DUT, determine an impedance of the second DUT based on the voltage and current signals, and determine a value of the state of the DUT based on the impedance and the data.

### BRIEF DESCRIPTION OF THE DRAWINGS

FIG. 1 is a circuit diagram of a system including a battery monitoring system coupled to a DUT, in an example.

FIG. 2 is a flowchart illustrating a method for collecting impedance data of the DUT via the battery monitoring system of FIG. 1, in an example.

FIG. 3 shows a frequency plot of an impedance feature that can support state estimation of a DUT, in an example.

FIGS. 4A, 4B, and 4C are frequency domain plots of impedance features that can support state estimation of a DUT, in various examples.

FIGS. 5A and 5B are frequency domain plots of impedance features that can support state estimation of a DUT, in various examples.

FIG. 6 is a plot that shows an example of variation of the discharge capacity of the DUT, in an example.

FIG. 7A and FIG. 7B are frequency domain plots of impedance features that can support state estimation of a DUT, in various examples.

FIG. 8 is a flowchart illustrating a method to determine a relationship between DUT state parameters and impedance features, in an example.

FIG. 9 is a plot that shows errors of temperature estimation of a DUT using various combinations of impedance features, in an example.

FIG. 10 is a plot that shows errors of SoC estimation of a DUT using various combinations of impedance features, in an example.

FIG. 11 is a plot that shows errors of SoC estimation of a DUT using various combinations of impedance features, in an example.

FIG. 12 is a plot that shows relationships between SoH of a DUT and various impedance features, in various examples.

FIG. 13 is a plot that shows errors of SoH estimation of a DUT using various combinations of impedance features, respectively, in an example.

FIG. 14 is a block diagram of a processor platform to perform state estimation of a DUT using impedance features, in an example.

### DETAILED DESCRIPTION

The same reference numbers or other reference designators are used in the drawings to designate the same or similar (either by function and/or structure) features.

As to be described herein, a device under test (DUT) can include but is not limited to a battery, which can include, for example, a battery cell, a battery module including one or more battery cells, or a battery pack including one or more battery modules. Other examples of the DUT may include any electrochemical device that has an electrical impedance, a charge storage device (e.g., a capacitor), or other devices having a frequency response. Although a battery module or a battery cell is used as a non-limiting example of a DUT in the discussions below, the same or similar approaches are also applicable to measurement of other types of DUTs. Furthermore, although impedance spectroscopy is used as a non-limiting example of frequency response measurement in the discussions below, the same or similar approaches are also appliable to measurement of any frequency response of a DUT through an electrical interface.

A battery cell impedance spectrum, which can be based on a ratio between the battery cell voltage and battery cell current in the frequency domain, has a strong correlation to a state of the battery cell, wherein the state can be but are not limited to, temperature, state-of-charge (SoC), and state-of-health (SoH) of the battery cell.

Battery temperature is one of the most critical states of a battery and, therefore, it is important to develop measurement/estimation techniques for keeping it in a safe operating range. Under the exposure to higher temperature (e.g., beyond 100° C.), Li-ion batteries (LIBs) are prone to thermal runaway tendencies, which are triggered as a series of internal exothermic reactions which can cause a catastrophic fire. Also, low temperatures can trigger deleterious reactions causing Li-metal plating, which significantly reduces the cell life and increase the propensity of internal short circuit of the battery. So, accurate monitoring battery temperature allows for optimization and control of the charge/discharge performance of a battery and reducing (or eliminating) the need to overcompensate for temperature estimation errors.

State of charge (SoC) may indicate a ratio of an available capacity to deliver charge and the maximum possible charge that can be stored in a battery. A fully charged battery can have an SoC of 100%, and a fully discharged battery can have an SoC of 0%. State of charge is also one of the most critical state parameters and thus, it is important to develop estimation techniques for measuring the SoC to ensure that consumers can use a wide range of cell capacity and to maintain a safe operating SoC range over the life of the cells. Accurate monitoring of battery state of charge allows for optimization and control of the performance such that, for example, the battery can be used over a wider range of state of charge due to the smaller errors in SoC estimation. If the SoC goes above 100%, it can also trigger the cell into thermal runaway tendencies, which are triggered as a series of internal exothermic reactions causing a catastrophic fire. So accurate state of charge allows better sizing of the battery packs and the estimation of the battery capacity and, correspondingly, accurate range of the vehicle.

State of health (SoH) may indicate the overall condition of a battery, such as the capacity to store and deliver charge, with respect to the condition of a new battery. For example, a battery's SoH may reveal the decline in the battery's capacity and available power as the battery ages over time. The constant usage of the battery leads to the degradation of various parts of the battery such as the decline in the lithium carrying capacity of the electrodes. This behavior in turn is quantified by the reduction in the battery's SoH. There are multiple SoH evaluation criteria, including the use of capacity fade, power fade and increase of internal resistance of the cell. There are multiple factors which influence the decline of the cell's SoH including operating conditions like C-rate, ambient temperature during operation and storage of the battery, etc.

Over time, the decline in the SoH of the battery may begin to limit the range of a electric vehicle powered by the battery. In addition, the state of power (SoP) of the cells may begin to decline as well. All these can impact the system that draws power from the battery, such as the driving range and the performance of a vehicle. Also, based on the predetermined SoH trajectories, the lifespan of the battery, as well as the lifespan of a system that incorporates the battery, such as an electric powertrain, can also be predicted.

Battery management systems (BMS) may play a critical role in the safe and efficient management of various states of a battery including, for example, temperature, SoC, SoH, or other parameters, based on the estimation of these parameters for each cell in the battery. One way by which the BMS system estimates temperature, SoC, and SoH is based on electrochemical impedance spectroscopy (EIS). For impedance measurements of a given cell, a harmonic excitation is applied over a frequency range from millihertz (mHz) to kilohertz (kHz), and a voltage across a battery cell, as well as a current that flows through the cell, can be measured/sensed by various measurement circuits. The voltage and current measurements are transformed into the frequency domain resulting in complex impedance values at each frequency. The impedance features (e.g. real components of the impedance values {Re(Z)}, imaginary components of impedance values {Im(Z)}, phases of the impedance values {∠Z}, and magnitudes of the impedance values {|Z|}) can be used to estimate various state parameters such as the temperature, the SoC, and the SoH of a given cell. EIS provides a non-destructive method of testing the system and allows rapid estimation of the state parameters of a battery cell at certain frequencies.

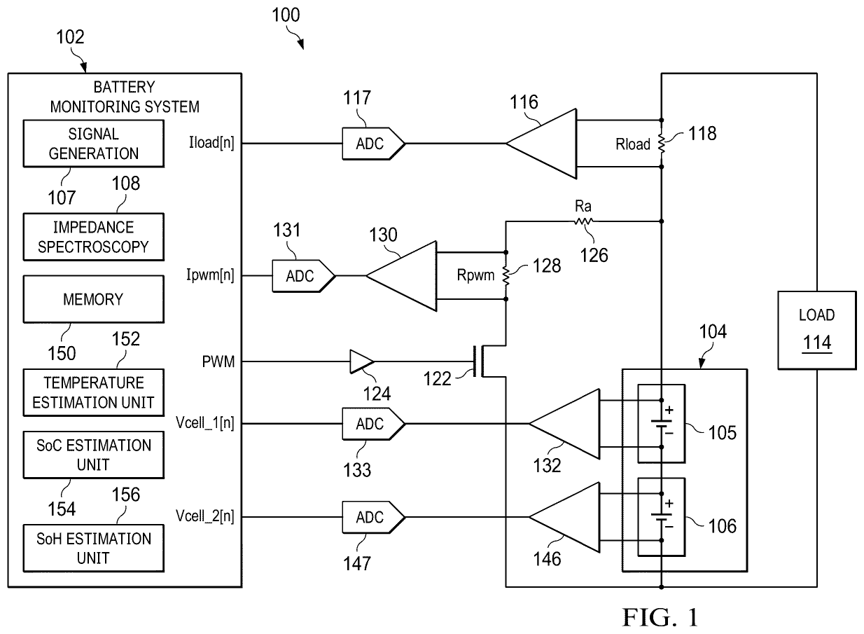

FIG. 1 is a circuit diagram of a system 100, including a battery monitoring system 102 that can estimate state parameters based on impedance features, according to an example. In the example of FIG. 1, battery monitoring system 102 is coupled to a DUT 104, which can include a battery module containing two cells 105, 106. In other examples, the DUT 104 can be a battery pack including 16 cells, 24 cells, or another number of cells connected in series. Each of 105, 106 can be a battery module that is connected in series and can contain multiple battery cells in parallel, with each such set of cells connected in parallel forming a battery module 105, 106. In other examples, the DUT may include other devices than a battery module or a battery pack.

The battery monitoring system 102 is configurable to provide one or more excitation signals to the battery module 104 (e.g., the DUT) and also to acquire one or more response signals from the battery module 104, which correspond to parameter(s) being measured. As described below, the excitation signal(s) include a frequency component.

The battery monitoring system 102 includes signal generation circuit 107 (also referred to as an excitation circuit), which is configurable to cause the excitation signals to be provided to the battery module 104. The battery monitoring system 102 also includes an impedance spectroscopy circuit 108, which is configurable to determine an impedance result, or spectra, of the battery module 104, such as based on a ratio of a measured or provided battery module 104 voltage signal and a measured or provided battery module 104 current signal.

Each component of the battery monitoring system 102 can be implemented in hardware (e.g., one or more application-specific integrated circuits (ASICs)), as software executed by a hardware processor, or a combination of software and hardware. For example, the battery monitoring system 102 can include a hardware processor or processing circuit configurable to execute instructions (e.g., stored in a non-transitory computer-readable medium, such as a memory). Responsive to the processor executing the instructions, the processor is configurable to perform the functionality described herein. The scope of the examples of this description is not limited to a particular physical implementation of any of the circuits of the battery monitoring system 102.

In the example of FIG. 1, the battery module 104 is coupled to a load 114, which includes an inverter to control a motor in an EV in one example. A load current amplifier 116 is configurable to receive a voltage across a load current sense resistor 118 (e.g., the load current amplifier 116 has a first input coupled to a first terminal of the load current sense resistor 118 and a second input coupled to a second terminal of the load current sense resistor 118), and to provide a voltage at its output that is proportional to the voltage across the load current sense resistor 118. Accordingly, the voltage provided at the output of the load current amplifier 116 is also proportional to the current provided to the load 114 by the battery module 104, and the battery monitoring system 102 receives the voltage provided at the output of the load current amplifier 116 as signal Iload. In some examples, the output of the load current amplifier 116 is provided to an analog-to-digital converter (ADC) 117, which converts the analog output of the load current amplifier 116 to a digital value. In these examples, the battery monitoring system 202 receives the digital value output of the ADC 117 as Iload.

The battery monitoring system 102 is configurable to generate a multi-cycle control signal, such as a pulse-width modulation (PWM) signal (labeled PWM), to control a transistor 122, which can be a field-effect transistor (FET). The battery monitoring system 102 provides the PWM signal to a gate driver 124, which drives a gate of the transistor 122 responsive to the PWM signal. A current measurement path is formed through resistor 126 (having a resistance Ra) and PWM current sense resistor 128 (having a resistance Rpwm) responsive to the transistor 122 conducting (e.g., being on/closed). No current flows through the current measurement path responsive to the transistor 122 not conducting (e.g., responsive to the transistor 122 being off/open).

A current measurement amplifier 130 has a first input coupled to a first terminal of the PWM current sense resistor 128 and a second input coupled to a second terminal of the PWM current sense resistor 128. The current measurement amplifier 130 is configurable to receive a voltage across the PWM current sense resistor 128, and to provide a voltage at its output that is proportional to the voltage across the PWM current sense resistor 128. Accordingly, the voltage provided at the output of the current measurement amplifier 130 is also proportional to the current through the current measurement path, including resistors 126, 128, and the battery monitoring system 102 receives the voltage provided at the output of the current measurement amplifier 130 as signal Ipwm. In some examples, the output of the current measurement amplifier 130 is provided to an ADC 131, which converts the analog output of the current measurement amplifier 130 to a digital value. In these examples, the battery monitoring system 102 receives the digital value output of the ADC 131 as Ipwm.

A battery voltage amplifier 132 is configurable to receive a first voltage across the battery cell 105 (e.g., the battery voltage amplifier 132 has a first input coupled to a first terminal of the battery cell 105 and a second input coupled to a second terminal of the battery cell 105), and to provide a second voltage at its output that is proportional to the voltage across the battery cell 105. The battery monitoring system 102 receives the second voltage provided at the output of the battery voltage amplifier 132 as signal Vcell_1. In some examples, the output of the battery voltage amplifier 132 is provided to an ADC 133, which converts the analog output of the battery voltage amplifier 132 to a digital value. In these examples, the battery monitoring system 102 receives the digital value output of the ADC 133 as Vcell_1.

In an example in which the battery module 104 includes an additional battery cell 106, a third battery voltage amplifier 146 is configurable to receive a voltage across the battery cell 106 similarly as the battery voltage amplifier 132 receives the voltage across the battery cell 105, as described. The battery monitoring system 102 thus receives the voltage provided at the output of the battery voltage amplifier 146 as signal Vcell_2. In some examples, the output of the battery voltage amplifier 146 is provided to an ADC 147, which converts the analog output of the battery voltage amplifier 146 to a digital value. In these examples, the battery monitoring system 102 receives the digital value output of the ADC 147 as Vcell_2.

As described, the battery monitoring system 102 is configurable to provide one or more excitation signals to the battery module 104 (e.g., the DUT). For example, the signal generation circuit 107 provides the multi-cycle PWM signal that controls the operation of the transistor 122, which sets the current through the current measurement path including resistors 126, 128. The current through the current measurement path is drawn from the battery module 104 (e.g., the cells 105, 106 in the example of FIG. 1).

The signal generation circuit 107 is configurable to control a duty cycle of the PWM signal to set a duration of enabling the transistor 122 in each cycle, which in turn can set an amount of current through the current measurement path. A duty cycle of 100% corresponds to the transistor 122 being always closed within a cycle of the PWM signal, and a duty cycle of 0% corresponds to the transistor 122 being always open within a cycle of the PWM signal. The transistor 122 has a resistance equal to Rds (on) when it is closed. The average current through the current measurement path is approximately equal to the duty cycle multiplied by the battery module 104 voltage, divided by the sum of Ra, Rpwm, Rds (on), and other resistances, such as trace resistance, along the current measurement path. The other resistances are ignored below for simplicity. Accordingly, the signal generation circuit 107, through the generation of the PWM signal, is configurable to vary the average current drawn from the battery module 104 between zero (e.g., responsive to a 0% duty cycle) and the battery module 104 voltage divided by the sum of Ra, Rpwm and Rds (on) (e.g., responsive to a 100% duty cycle). The current through the resistors 118 and 128 equals the current provided by the battery pack 204 and is used for the EIS measurements.

As described, the battery monitoring system 102 receives an indication of the current through the resistors 118 and 128 as the output of the current measurement amplifier 130 (Ipwm) and the current measurement amplifier 116 (Iload). The battery monitoring system 102 is also configurable to acquire one or more response signals from the battery module 104, which correspond to parameter(s) being measured. For example, the Vcell_1 signal provided by the battery voltage amplifier 132 corresponds to the AC voltage across battery cell 105. Accordingly, the battery monitoring system 102 is configurable to provide an excitation signal to the battery module 104, such as by varying the current through resistor 128 by controlling the duty cycle of the transistor 122 over time. The battery monitoring system 102 is also configurable to measure a parameter (e.g., the voltage across the battery cell 105) that is responsive to the excitation signal.

For example, the battery monitoring system 102 receives outputs from ADCs 117, 131, 133, and 147 representing, respectively, the load current (Iload), the current excitation signal (Ipwm), and the voltages of the battery module 104 (Vcell_1, Vcell_2) in the time domain. The battery monitoring system 102 reconstructs the current and voltage across the battery cell 105, 106 responsive to Ipwm, Iload, and Vcell_1 or Vcell_2, respectively. For example, a voltage for battery cell 105 can be represented as V_{cel1_1} [n], for each time sample n. Likewise, the current for battery cells 105, 106 can be represented as:

$${I}_{cell} [ n ] = - ( {I}_{load} [ n ] + {I}_{pwm} [ n ] ) \qquad ( 1 )$$

for each time sample n. Similar values for the battery cell 106 (e.g., Vcell_2 [n]) can be determined using the corresponding values (e.g., Vcell_2) for the battery cell 106. In this description, positive current indicates a current flowing into the battery module 104, and thus negative current indicates a current flowing out of the battery module 104. The Vcell voltages and the Ipwm, Iload currents can have frequency components at a set of frequencies due to, for example, the PWM signal having harmonics and/or the PWM signal having the set of frequencies.

In some examples, the battery monitoring system 102 can apply a transform operation, such as a discrete Fourier transform (DFT) operation, on samples of measurements of Ipwm, Iload, Vcell_1, and Vcell_2 (e.g., as EIS measurements) to transform the measurements from the time domain to the frequency domain. The transform operations allow other parameters, such as impedance, to be computed in the frequency domain to generate a spectroscopy of that parameter, such as an impedance spectroscopy. A DFT of each of the current and voltage time domain signals (e.g., Ipwm, Iload, and Vcell_1 (for battery cell 105) or Vcell_2 (for battery cell 106)) can be performed using a number of samples (e.g., n) of the time domain signals. The results of these DFTs are frequency domain representations of the current and voltage signals. The impedance for the battery cell 105 at each discrete frequency index k can be computed responsive to computing the frequency domain representations of the current and voltage signals as follows:

$${Z}_{cell \_ 1} [ k ] = \frac{{V}_{cell \_ 1} [ k ]}{{I}_{cell} [ k ]} \qquad ( 2 )$$

In an example, the battery monitoring system 102 can apply a window function on the samples acquired by the battery monitoring system 102 and perform the DFT on the samples with the window function applied. Provided that the sampling rate exceeds twice the signal bandwidth, the DFT can recover the underlying response spectra. Provided that the measured signals are periodic, the duration of the window function can be a multiple of the period of the measured signals.

In an example, the battery monitoring system 102 is configurable to control the transistor 122 to provide a sinusoidal current excitation signal (or a signal that approximates a sinusoid) to the battery module 104. In one example, a sequence of PWM signals having a frequency higher than the excitation frequency can be provided, where the sequence of PWM signals have different amplitudes to approximate a sinusoid. The excitation signal can approximate a single-tone sinusoidal signal, or can include multiple sequences of PWM signals having different frequencies to approximate a multi-tone sinusoidal signal. The excitation signal can have frequency components corresponding to frequency ranges of the result of the transform to the frequency domain. For example, the frequency components can be represented by spectral components in a DFT frequency bin.

As described above, the battery monitoring system 102 is configurable to perform a transform operation, such as a DFT, on the measured current excitation signal (e.g. the Ipwm signal), on the measured load current signal (e.g. Iload) and on the voltage response signal (e.g. the Vcell_1 signal) to transform the signals from the time domain to the frequency domain. In one example, the impedance spectroscopy circuit 108 includes circuitry configurable to perform the DFT. In another example, the battery monitoring system 202 includes a hardware processor configurable to execute instructions (e.g., stored in a non-transitory, computer-readable medium, such as a memory). Responsive to the processor executing the instructions, the processor can perform the DFTs. The battery module 104 impedance spectra (e.g., an EIS measurement) can be determined responsive to determining a ratio between the transformed voltage values (e.g., voltage DFT) and the transformed current values (e.g., current DFT) is, which is useful to characterize the battery module 104. As described hereinafter, the SoC, SoH, or temperature (T) parameters can be determined from the EIS measurement of the battery module 104.

In some examples, the impedance response Z of the battery 104 is a function of the frequency (f) and one or more states, such as state of charge (SoC), state of health (SoH), and temperature (T), which can be represented as

$$Z = g ( f , S o C , S o H , T ) \qquad ( 3 )$$

where g(⋅) is a function. As to be described herein, an inverted form of function g(⋅) can be determined, and the inverted form of the function can receive the impedance response Z and the associated frequencies (which collectively provide the impedance features) as inputs, and output a particular state, without the need to input other states. For example, the inverted form can receive impedance features of a DUT as an input and, for example, output a temperature estimate of a DUT without receiving SoH and SoC states of the DUT as inputs, output an SoH estimate of the DUT without receiving SoC and temperature states of the DUT as inputs, or output an SoC estimate of the DUT without receiving SoH and temperature states of the DUT as inputs.

In one example, the battery monitoring system 102 is configurable to perform impedance-based characterization and the state parameter estimation method by taking the impedance measurements across a range of various operation parameters (e.g., T, SoC, and SoH) and then characterizing the battery cell behavior. The battery monitoring system 102 then develops a functional mapping by performing a curve fit between one or more impedance features and a state to be characterized (e.g., T, SoC, SoH, etc.), to provide the aforementioned inverted functions.

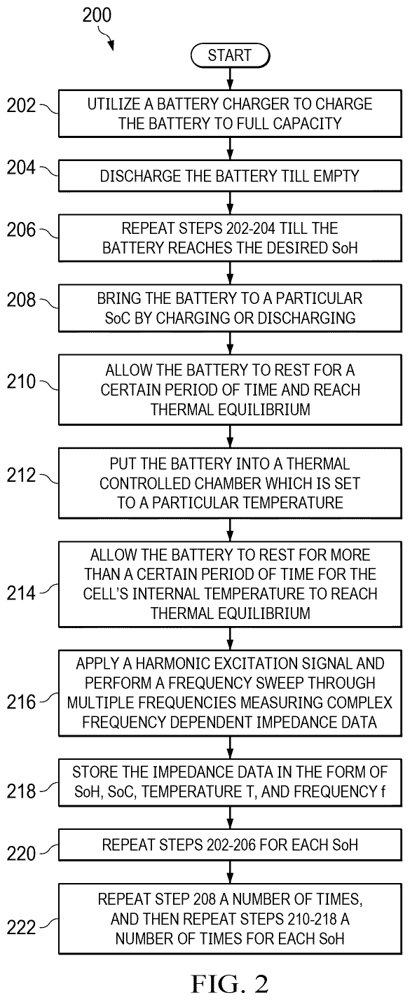

FIG. 2 is a flowchart illustrating an example of a method 200 for collecting impedance data of the battery pack/DUT 104 experimentally via the battery monitoring system 102. At operation 202, a battery charger is utilized to charge the battery module 104 to full capacity. At operation 204, the battery module 104 is discharged till empty. At operation 206, operations 202 and 204 are repeated till the battery module 104 reaches the desired State of Health {SoHᵢ} where i∈{1, . . . , l}. At operation 208, the battery pack 104 is brought to a particular State of Charge {SoCⱼ} where j∈{1, . . . J}, by charging or discharging. At operation 210, the battery module 104 is allowed to rest for a certain period of time (e.g., 3 hours) and reach thermal equilibrium. At operation 212, the battery module 104 is put into a thermal controlled chamber which is set to a particular temperature. At operation 214, the battery module 104 is allowed to rest for more than a certain period of time (e.g., 3 hours) for the cell's internal temperature to reach thermal equilibrium. At operation 216, a harmonic excitation signal is applied by the battery monitoring system 102 to perform a frequency sweep through frequencies {fₗ} where l∈{1, . . . , L} measuring complex frequency dependent impedance data. At operation 218, the impedance data is stored in a memory 150 of the battery monitoring system 102 in the form of SoHᵢ, SoCⱼ, temperature Tₖ, and frequency fₗ. At operation 220, operations 202-206 are repeated for each SoHᵢ where i∈{1, . . . , l}. Finally, at operation 222, repeat operation 208 J times and then repeat operations 210-218 J×K times for each SoHᵢ.

The resulting impedance data from the above impedance measurement flow 200 can be a matrix of Z (i, j, k, l) where i∈{1, . . . , l}, j∈{1, . . . , J}, k∈{1, . . . , K}, l∈{1, . . . , L} with the dimensions of I×J×K×L. The resulting matrix consists of the impedance measurements at the I SoH's, J SoC's, KT's and L frequencies. For a given SoH level, the corresponding impedance measurements can have a matrix with dimensions J×K×L.

Temperature Estimation from Impedance Data

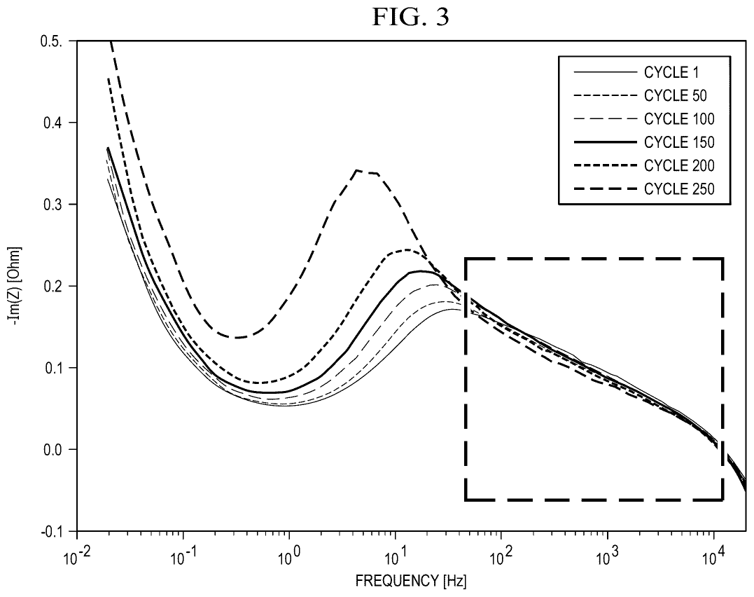

FIG. 3 shows an example of one of the impedance features, e.g., the negative imaginary component (−Im(Z)) of the measured impedance plotted versus frequency of DUT 104, such as a coin cell (e.g., 160 mAh), after a given number of charge/discharge cycles, e.g., cycle 1, 50, 100, 150, 200 and 250, at T=20° C. Note that the number of charge/discharge cycles may indicate the SoH of the DUT 104. As shown in FIG. 3, the imaginary components of the impedance of the DUT 104, for this particular temperature (T=20° C.), are approximately the same across different SoHs (represented by the number of charge/discharge cycles) and hence are largely insensitive to SoH, for higher frequencies, such as at a frequency above 100 Hz. Therefore, in this frequency region, the impact of SoH on the imaginary component of impedance can be ignored. Note that for larger capacity cells, the range of impedance values, as well as the frequency range where the imaginary components of the impedance are approximately the same across different SoHs, may be different from as shown in FIG. 3.

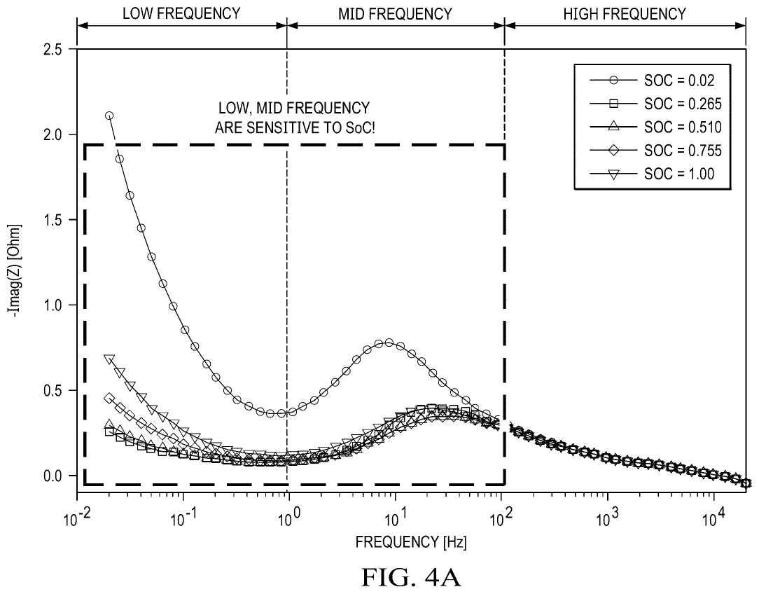

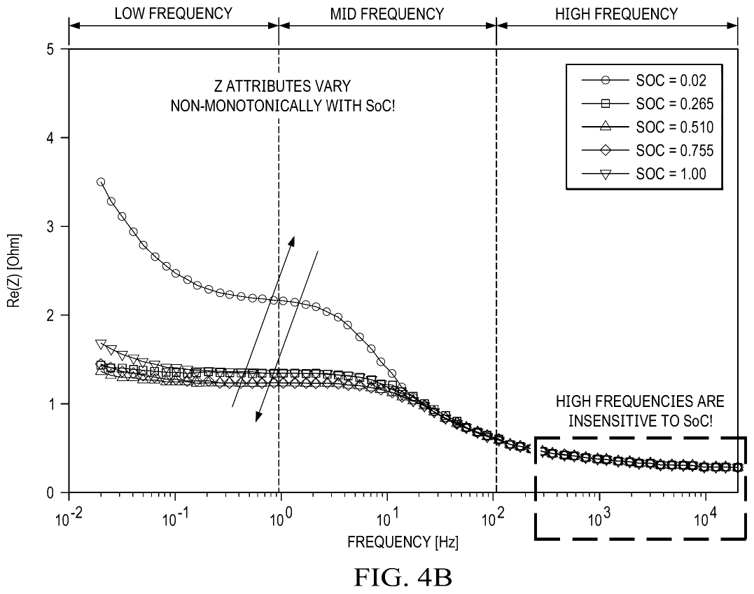

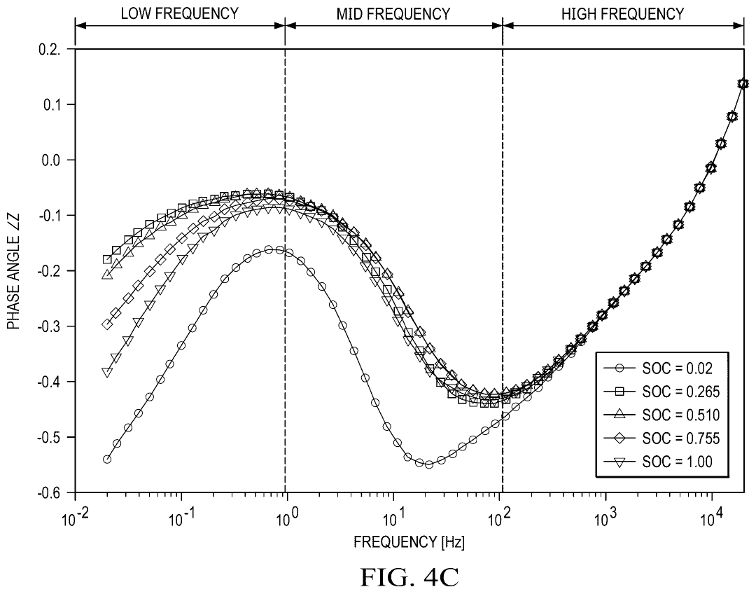

For estimating the temperature from impedance values, a temperature estimation unit 152 of the battery monitoring system 102 is configurable to build separate relations for each state of charge {SoCⱼ}, In one example, this process requires knowing the SoC and additional memory 150 to store weights for different SoCs. As such, determining the frequency {fₗ} so that effects of SoCs can be neglected would be helpful. FIGS. 4A-4C show various impedance features of DUT 104, such as an example of a coin cell represented in FIG. 3, at different SoC levels and at 20° C. cell temperature for frequencies between 0.02 Hz and 20 kHz. Specifically, FIG. 4A shows the negative imaginary part of the impedance (e.g., −Im(Z)), FIG. 4B shows the real part of the impedance (e.g., Re(Z)), and FIG. 4C shows the phase angle of the impedance (e.g., ∠Z) at T=20° C. for different SoC values. It can be seen from the figures that at higher frequencies (e.g., above 100 Hz), various impedance features, including imaginary components (shown in FIG. 4A), real components (shown in FIG. 4B), and phases (shown in FIG. 4C) are largely insensitive to the SoC variations.

Based on the above analysis for the frequencies fₗ>100 Hz, the impact of states SoC and SoH on the impedance response on temperature estimation can be ignored. Accordingly, the functional form for impedance can be denoted as:

$$Z = \hat{g} ( {T}_{k} , {f}_{l} ) \approx \frac{1}{IJ} {\sum }_{j = 1}^{J} {\sum }_{i = 1}^{i} g ( S o {H}_{i} , S o {C}_{j} , {T}_{k} , {f}_{l} ) for {f}_{l} > 100 Hz \qquad ( 4 )$$

Either averaging across the SoC and/or SoH or choosing a specific value, the resulting impedance data is a function of temperature T∈

$${\{ {T}_{k} \}}_{k = 1}^{K}$$

and frequency f∈

$${\{ {f}_{l} \}}_{l = 1}^{L}$$

resulting in a K×L
dimension matrix. Based on this analysis, the temperature estimation unit 152 can be configured to build a functional mapping h, which can represent an inverted form of the function g(⋅), to estimate the temperature from the impedance features based on the following relation:

$$\hat{T} = h ( Z ( {f}_{l} ) ) \qquad ( 5 )$$

To perform temperature estimation for a DUT, the temperature estimation unit 152 can receive a set of impedance features Z at a set of frequencies fₗ, and provide those as inputs to the functional mapping h to provide the temperature estimate \hat{T}. The impedance features Z can be of the same DUT, or another DUT having similar characteristics (e.g., similar chemistry) as the DUT.

SoC Estimation from Impedance Data

As shown in the figures, the impedance of the DUT can be significantly affected by both the SoC and temperature (T) at lower frequencies (e.g., fₗ<100 Hz). To uniquely estimate SoC from impedance data, the effects of temperature (T) on the impedance can be separated from the SoC. In an example, an SoC estimation unit 154 of the battery monitoring system 102 is configurable to determine the SoC from the impedance based on two methods, as to be described below.

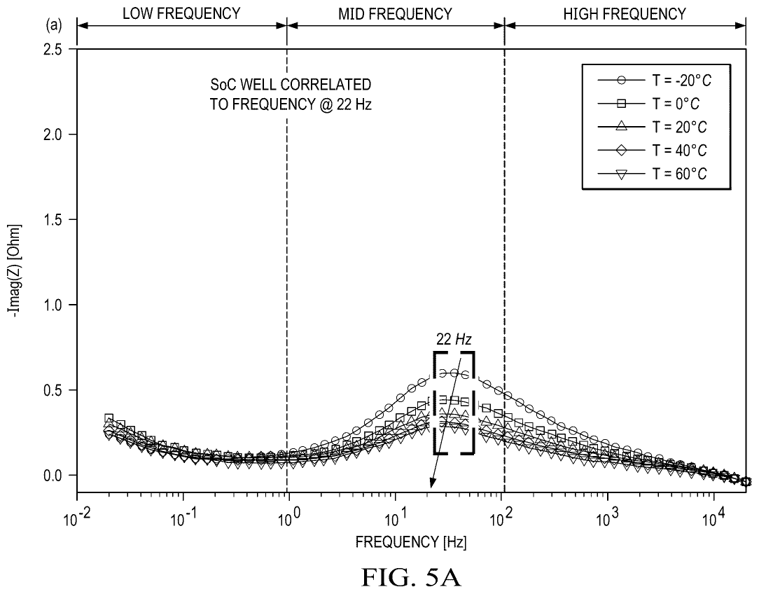

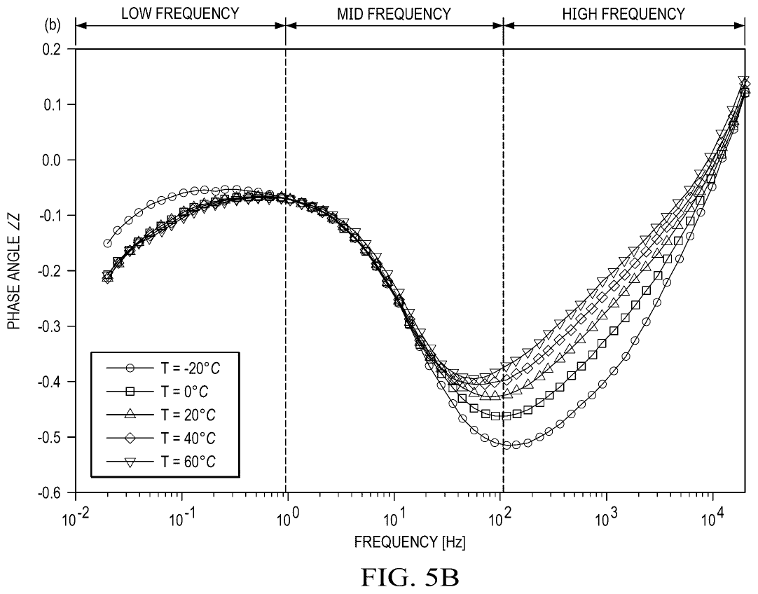

Method 1: If the temperature (T) of the DUT 104 is completely unknown, then the frequency range of the impedance features can be chosen such that the impedance features are largely insensitive to the temperature, and a mapping function between impedance features and SoC can be built for such a frequency range. FIGS. 5A and 5B depict impedance features, e.g., −Im(Z) and Phase angle (∠Z) as a function of frequency, respectively, for DUT 104 (e.g., an example of a coin cell represented in FIG. 3) at a given SoC at different temperatures for frequencies between 0.02 Hz and 20 KHz. As shown in FIGS. 5A and 5B, the frequencies have been divided into three regions: low frequency [<10 mHz, 1 Hz], mid frequency [1 Hz, 100 Hz] and high frequency [100 Hz, >10 KHz]. FIG. 5A shows that the imaginary component of the impedance (Im(Z)) in the low and high frequency regions are largely independent of the temperature. In addition, FIG. 5B shows that the phase angle of impedance (phase angle (∠Z)) in at least part of the mid frequency region is largely independent of the cell temperature.

Based on the above analysis for the various frequencies, the impact of temperature (T) on the impedance features, for a particular SoC, can be ignored for certain frequencies. For example, for phase angle ∠Z, the functional form for impedance can represented as follows

$$∠ Z = \hat{g} ( S o {C}_{j} , {f}_{l} ) \approx \frac{1}{IK} {\sum }_{k = 1}^{K} {\sum }_{i = 1}^{I} g ( S o {H}_{i} , S o {C}_{j} , {T}_{k} , {f}_{l} ) \qquad ( 6 )$$

Accordingly, the SoC estimation unit 154 can either average the impedance feature values (e.g., phase angle) across different temperatures, the resulting impedance data is a function of state of charge SoC ∈

$${\{ S o {C}_{j} \}}_{j = 1}^{J}$$

and frequency f∈

$${\{ {f}_{l} \}}_{l = 1}^{L}$$

resulting in a J×L dimension matrix. Based on this analysis, the SoC estimation unit 154 can build a functional mapping. To estimate the state of charge of a DUT from the impedance features, the SoC estimation unit 154 can receive a set of impedance features of the DUT (or another DUT with similar characteristics) with the associated frequencies as inputs, and provide those to the functional mapping to provide the SoC estimate.

Method 2: If the temperature of the cell is known, then for each temperature (T), the SoC estimation unit 154 can build a different functional mapping to estimate state of charge (SoC). In such example, the SoC estimation unit 154 can receive a set of impedance features with the associated frequencies, as well as a temperature, as inputs, select a functional mapping based on the temperature, and provide the set of impedance features and the associated frequencies to the selected functional mapping to provide the SoC estimate.

SoH Estimation from Impedance Data

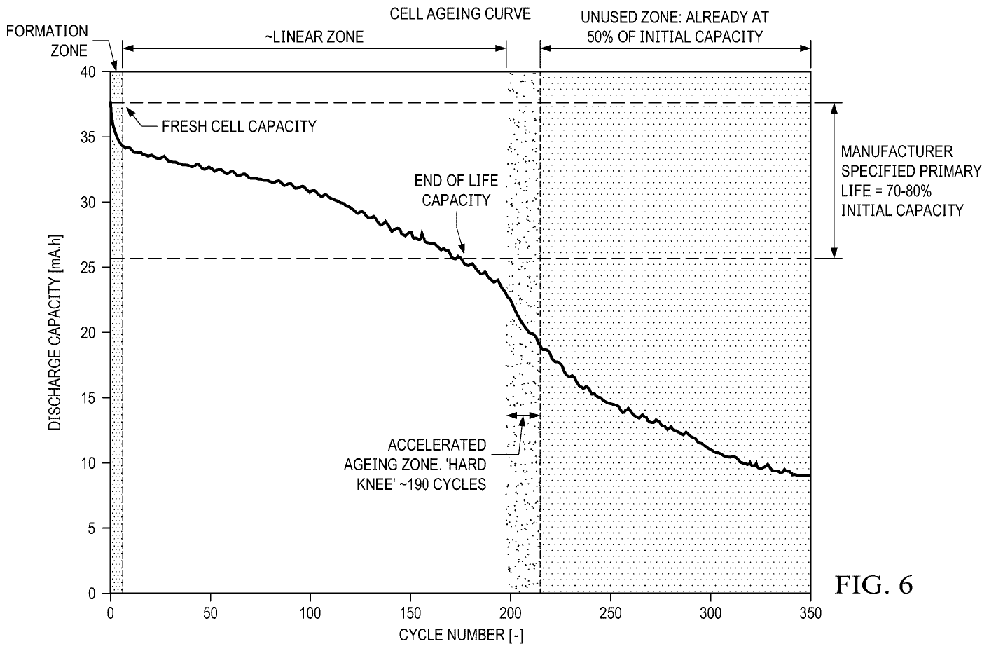

FIG. 6 shows an ageing curve of the discharge capacity of DUT 104 (e.g., an example of a coin cell represented in FIG. 3) as a function of the number of charge and discharge cycles at T=20° C. This ageing curve is often referred to as the capacity fade curve. There are three zones in the capacity fade curve as shown in FIG. 6, which are the formation zone, the linear zone, and the accelerated ageing zone. Specifically,
1) Formation zone: the first charge and discharge cycle are called formation cycle. During the first formation cycle the charging process leads to the development of a protective layer on the top of the graphite anode of the battery cell 105. This layer is known as solid-electrolyte interface (SEI) layer which results in the loss of lithium and hence a capacity fade.
2) Linear ageing zone: this zone is where the majority of Li-ion cells operate during their lifetime. During these cycles, the capacity fade of the battery cell 105 occurs in an almost linear fashion. This zone lasts up to 150-180 cycles for small capacity cells (<1 Ah). For large capacity cells (˜100 Ah), this zone can last up to 2400 cycles. This is the manufacturer's specified primary life of the cell at 70-80% of initial capacity.
3) Accelerated ageing zone: this zone represents the accelerated ageing, i.e., ‘hard knee’ point for the cell capacity fade curve. It occurs close to ˜190 cycles for small capacity cells and leads to a sudden drop in the capacity of about 20% within 10 cycles. This zone occurs close to ˜2800 cycles for large capacity cells. Beyond this zone, the battery cell 105 goes into an unused zone where the cell capacity drops below 50% of the initial value.

It is appreciated that SoH is a very slowly changing state parameter as it changes over the lifetime of the battery cell 105. For this reason, SoH can be measured or estimated once in a while, e.g., once in a month. For example, SoH of an electric vehicle battery declines from 100% to 80% over a 10 year period. This behavior implies that SoH declines by only 2% each year or 0.167%, which means the frequency of SoH estimation can be quite low.

For SoH estimation, a SoH estimation unit 156 of the battery monitoring system 102 can determine a relationship between the impedance features and SoH using experimental data, such as data from method 200. In an example, the impedance values/data for a DUT (e.g., a battery cell) is generated by cycling the cell at 25° C. and taking the impedance measurements at multiple frequencies between 0.02 Hz and 20 kHz. This impedance data has been used subsequently for the analysis to determine the relationship.

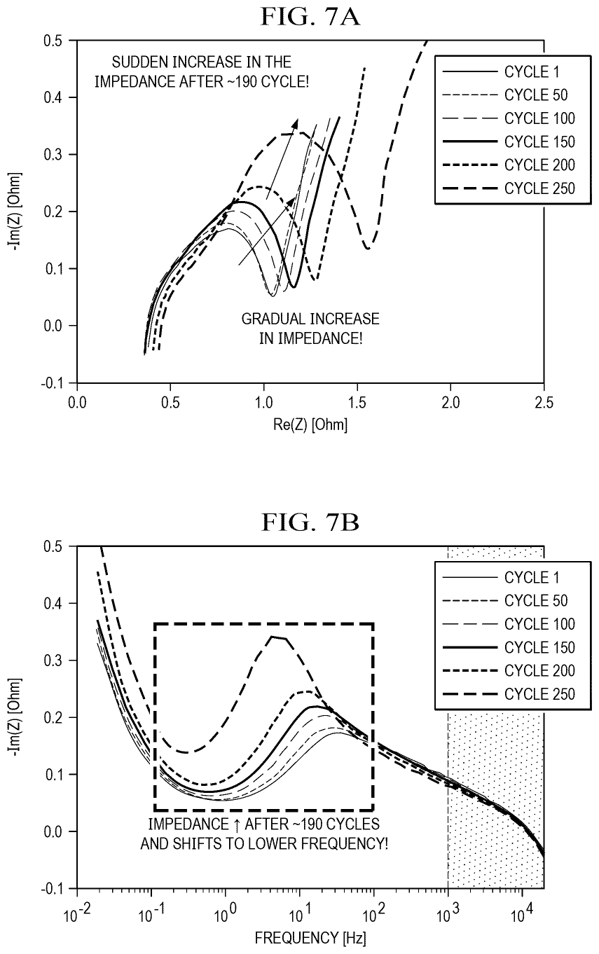

FIGS. 7A and 7B show examples of impedance features as a function of a number of charge/discharge cycles of DUT 104, such as an example of a coin cell represented in FIG. 3. FIG. 7A shows the modified Nyquist plot of the impedance feature, e.g., −Im(Z) as a function of Re(Z). Notice that the impedance of the battery cell 105 increases over cycling, including both the real and imaginary components of the impedance. As shown in FIG. 7A, there is a sudden increase in the impedance from cycle 200 to cycle 250, which can be correlated to the onset of knee point in the ageing curve when the capacity of the cell suddenly drops. FIG. 7B shows the real component of the impedance Re(Z) as a function of the frequency for different numbers of charge/discharge cycles. As shown by FIG. 7B, the peak of the impedance curve shifts towards lower frequencies and higher values of real component of impedance. Both FIGS. 7A and 7B show that the impedance (and the impedance features at different frequencies) of the DUT vary with the number of charge/discharge cycles, which can indicate the SoH of the DUT. Accordingly, the impedance features can be used to estimate the SoH of the DUT.

For a battery cell, SoH can be defined as the ratio of the current capacity (capacity) to the capacity of the new battery cell (capacity,) as follows:

$$S o H = \frac{capacity}{{capacity}_{0}} \qquad ( 7 )$$

By choosing a specific value for the temperature (T) and the SoC, the SoH estimation unit 156 can determine a function that relates impedance features to the SoH ∈

$${\{ S o {H}_{i} \}}_{i = 1}^{I}$$

and frequency

$$f ∈ {\{ {f}_{l} \}}_{l = 1}^{L} .$$

The resulting dimensions of the impedance matrix are I×L. Based on the analysis, the SoH estimation unit 156 builds a functional mapping h that relates a set of impedance features and the associated frequencies to SoH as follows:

$$= h ( Z ( {f}_{l} ) ) \qquad ( 8 )$$

To perform SoH estimation of a DUT, the SoH estimation unit 156 can receive a set of impedance features Z of the DUT (or another DUT with similar characteristics) at a set of frequencies fₗ, and provide those as inputs to the functional mapping h to provide the SoH estimate [symbol] .

State Parameter Estimation with Basis Functions

In one example, the battery monitoring system 102 uses a physics-based model to generate the impedance data, although the battery monitoring system 102 can also utilize an experimental setup to provide a similar set of impedance responses for the DUT 104 under different operation conditions. Specifically, for temperature estimation, with each cell characterization dataset

$$SoC ∈ {\{ {SoC}_{j} \}}_{j = 1}^{J} ,$$

the battery monitoring system 102 is configurable to make the impedance measurements across a range of frequencies

$$f ∈ {\{ {f}_{l} \}}_{l = 1}^{L}$$

at different temperatures

$$T ∈ {\{ {T}_{k} \}}_{k = 1}^{K} .$$

The frequencies are such that where impedance is independent of the SoC and the SoH, e.g., frequencies

$$f ∈ {\{ {f}_{l} \}}_{l = 1}^{L} ( {f}_{l} > 100 Hz )$$

as described above. In one example, the impedance values could be at multiple frequencies or some single frequency f_{L}.

In one example, the impedance from temperature estimation can be represented as the following matrix, where each value in this matrix represents the impedance measurements at a k^{th} temperature and l^{th} frequency:

$$Z = [ \begin{matrix}{Z}_{1 , 1} & … & {Z}_{1 , L} \\ ⋮ & ⋱ & ⋮ \\ {Z}_{K , 1} & … & {Z}_{K , L}\end{matrix} ] ∈ {ℂ}^{K \times L} \qquad ( 9 a )$$

For SoC estimation, with each cell characterization dataset, the battery monitoring system 102 is configurable to make the impedance measurements across a range of frequencies

$$f ∈ {\{ {f}_{l} \}}_{l = 1}^{L}$$

at different

$$SoC ∈ {\{ {SoC}_{j} \}}_{j = 1}^{J}$$

and temperatures

$$T ∈ {\{ {T}_{k} \}}_{k = 1}^{K} .$$

These frequencies are such that certain impedance features are independent of the temperature (T) and the SoH as shown in FIGS. 5A and 5B. In one example, the impedance values could be at multiple frequencies or at a single frequency f_{L}.

In one example, the impedance from SoC estimation can be represented as the following matrix, where each value in this matrix represents the impedance measurement at the j^{th} state of charge and l^{th} frequency.

$$Z = [ \begin{matrix}{Z}_{1 , 1} & … & {Z}_{1 , L} \\ ⋮ & ⋱ & ⋮ \\ {Z}_{I , 1} & … & {Z}_{I , L}\end{matrix} ] ∈ {ℂ}^{I \times L} \qquad ( 9 b )$$

For SoH estimation, the battery monitoring system 102 is configurable to collect the impedance data at different SoH for the aging of the DUT 104. After the cell characterization is performed, the battery monitoring system 102 is configurable to determine the impedance (Z) as a function of frequency (f), SoC, temperature (T) and SoH.

In one example, the impedance data from SoH estimation can be represented as the following matrix, where each value in this matrix represents the impedance measurements at i^{th} state of health and l^{th} frequency.

$$Z = [ \begin{matrix}{Z}_{1 , 1} & … & {Z}_{1 , L} \\ ⋮ & ⋱ & ⋮ \\ {Z}_{J , 1} & … & {Z}_{J , L}\end{matrix} ] ∈ {ℂ}^{J \times L} \qquad ( 9 c )$$

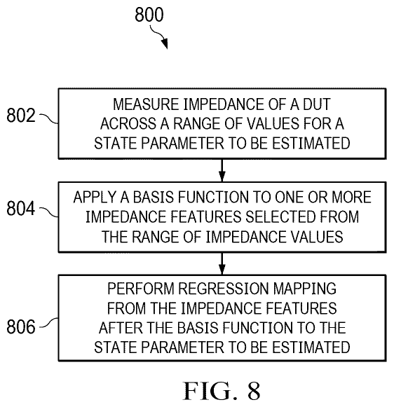

FIG. 8 is a flowchart illustrating an example of a method 800 performed to determine a relationship between a range of values of the state, e.g., temperature, SoC, and SoH, of the DUT 104 and the set of measured impedance data values. Method 800 can be performed by, for example, the temperature estimation unit 152, the SoC estimation unit 154, and/or the SoH estimation unit 156 of battery monitoring system 102.

At operation 802, impedance of the DUT 104 is measured across a range of values for a state parameter to be estimated. Specifically, for temperature estimation, impedance is measured across a range of temperatures Tₖ, k=1, . . . , K, correspondingly the impedance values are measured at a selected frequency fₗ (can be more than one frequency) for these temperatures denoted as Z_{k,l}. For SoC estimation, impedance is measured across a range of SoC values SoCⱼ, j=1, . . . , J correspondingly the impedance values are measured at a selected frequency fₗ (can be more than one frequency) for these states of charge denoted as Z_{j,l}. For SoH estimation, the impedance is measured across a range of state of health SoHᵢ, i=1, . . . , I. The impedance values are measured at selected frequencies fₗ (can be more than one frequency) for these SoH's and are denoted as Z_{i,l}.

At operation 804, a basis function is applied to one or more impedance features selected from the range of impedance values. Specifically, from the impedance values Z_{i,l}, Z_{j,l}, or Z_{k,l}, the real valued impedance features are selected, including a combination of one or more of Re(Z), Im(Z), ∠(Z) and ∥Z∥ and then a basis function is applied to them. In one example, for SoH estimation using Z_{i,l}, the resulting function is represented as follows:

$${x}_{i} = B ( {Z}_{i , l} ) for i = 1 , … I \qquad ( 10 )$$

Here, B is a vector of basis functions that transform the impedance features as follows: B: [symbol] → [symbol] ^{N} will transform the impedance features to a vector of N real-valued impedance features. Same holds for xⱼ=B (Z_{j,l}) and xₖ=B(Z_{k,l}).

In one example, the impedance values are mapped into a vector of real-values by selecting one or more impedance features and applying a basis function to them. In one example, the basis function B(x) is of the form 1, x^{r}, exp(x), log(x) where r=rational number. This feature creation allows to model any non-linear relation that exists between the measured impedance and the state (temperature, SoC, SoH, etc.) to be estimated.

In one example, xₖ can contain multiple transformations of the same real-valued impedance feature (e.g. both ∠Z_{k,l} and (∠Z_{k,l})²), in which case the resulting temperature estimate can be interpreted as a nonlinear combination of impedance features. Likewise, xᵢ can contain multiple transformations of the same real-valued impedance feature (e.g. both ∠Z_{i,l} and (∠Z_{i,l})²), in which case the resulting SoH estimate can be interpreted as a nonlinear combination of impedance features. In one example, xⱼ can contain multiple transformations of the same real-valued impedance feature (e.g. both φZ_{j,l} and (φZ_{j,l})²), in which case the resulting SoC estimate can be interpreted as a nonlinear combination of impedance features. In one example, the impedance can be from multiple frequencies as well.

Assuming the total number of generated features are N, the resulting data can be expressed as a feature vector X. For temperature estimation, each row of X represents the vector of N values at a given temperature while each column represents an impedance feature of the impedance at different values of temperature Tₖ, k=1, . . . , K.

$$X = [ \begin{matrix}- & {x}_{1}^{T} & - \\ & ⋮ & \\ - & {x}_{K}^{T} & -\end{matrix} ] ∈ {ℝ}^{K \times N} . \qquad ( 11 a )$$

For SoC estimation, each row of X represents the vector of N values at a given state of charge while each column represents a feature generated from the impedance feature of the impedance at different values of state of charge SoCⱼ, j=1, . . . , J.

$$X = [ \begin{matrix}- & {x}_{1}^{T} & - \\ - & {x}_{J}^{T} & -\end{matrix} ] ∈ {ℝ}^{J \times N} . \qquad ( 11 b )$$

For SoH estimation, each row of X represents the vector of N values at a given SoH while each column represents n impedance features of the impedance (Z) at different values of impedance Zᵢ, i=1, . . . , I.

$$X = [ \begin{matrix}- & {x}_{1}^{T} & - \\ - & {x}_{I}^{T} & -\end{matrix} ] ∈ {ℝ}^{I \times N} . \qquad ( 11 c )$$

At operation 806, regression mapping is performed from the impedance feature X after the basis function to the state parameter, e.g., temperature, SoC, SoH to be estimated. Specifically, for temperature estimation, the temperature estimation unit 152 is configurable to perform a regression mapping from these impedance feature X to the temperature T using following set of equations. The optimal weight vector w* is determined by linear regression by minimizing the sum of squared error between estimated temperature \hat{T} and true temperature T (over the temperature of interest).

$$\hat{T} = Xw \qquad ( 12 )$$

$$where ,$$

$${w}^{N \times 1} = {[ {w}_{1} … {w}_{N} ]}^{T} \qquad ( 13 )$$

$${w}^{*} = {arg min}_{w} {‖ T - \hat{T} ‖}_{2} = {arg min}_{w} {{\sum }_{k = 1}}^{K} {( {T}_{k} - {x}_{k}^{T} w )}^{2} \qquad ( 14 )$$

wherein estimated temperature [symbol] is a weighted sum of the feature vector Xₖ, and to determine these optimal set of weights w*, the squared sum of residuals is minimized.

For SoC estimation, the SoC estimation unit 154 is configurable to perform a regression mapping from the impedance feature vector X to the SoC using the following set of equations. The optimal weight vector w* is determined using linear regression by minimizing the sum of the squared error between the estimated state of charge [symbol] and the true state of charge SoC (over the desired range of state of charge values).

$$= Xw \qquad ( 15 )$$

$$where ,$$

$${w}^{N \times 1} = {[ {w}_{1} … {w}_{N} ]}^{T} \qquad ( 16 )$$

$${w}^{*} = {arg min}_{w} {‖ SoC - ‖}_{2} = {arg min}_{w} {{\sum }_{j = 1}}^{J} {( {SoC}_{j} - {x}_{j}^{T} w )}^{2} \qquad ( 17 )$$

The estimated state of charge [symbol] is a weighted sum of the feature vector Xⱼ, and to determine these optimal set of weights w*, the squared sum of residuals is minimized. Until now, the description is provided for the Method 1 above, where for the frequencies where the impedance is independent of the temperature.

For estimating the SoC from the impedance values, either separate relations can be built for each temperature {Tₖ}, although this method requires knowing the temperature and additional memory to store weights for each temperature values {Tₖ}. If the temperature of the cell is known (see Method 2 above), the regression mapping for state of charge is built for each temperature value, i.e., instead of averaging across the temperature, the weights are calculated for each temperature. So, all the equations (12)-(17) above remain the same except that they are all at a specific temperature value. Hence, the resulting set of weights are represented as follows at each temperature.

$${w}^{*} ( T ) = {arg min}_{w} {‖ SoC - ‖}_{2} = {arg min}_{w} {{\sum }_{j = 1}}^{J} {( {SoC}_{j} - {x}_{j}^{T} w )}^{2} \qquad ( 18 )$$

For SoH estimating, the SoH estimation unit 156 is configurable to perform a regression mapping from the impedance feature vectors X to the state of health SoH using the following set of equations. The optimal weight vector w* is determined by linear regression, which minimizes the sum of the squared error between estimated state of health [symbol] and the true state of health SoH (over the state of health of interest).

$$= Xw \qquad ( 19 )$$

$$where ,$$

$${w}^{N \times 1} = {[ {w}_{1} … {w}_{N} ]}^{T} \qquad ( 20 )$$

$${w}^{*} = {arg min}_{w} {‖ SoH - ‖}_{2} = {arg min}_{w} {{\sum }_{i = 1}}^{I} {( {SoH}_{i} - {x}_{i}^{T} w )}^{2} \qquad ( 21 )$$

The estimated state of health [symbol] is a weighted sum of the feature vector xᵢ, and to determine these optimal set of weights w*, the squared sum of residuals is minimized.

In one example, the impedance data for creation of the model/relationship by the state estimation units 152, 154, and 156 can be divided into two sets: the first set is used for training of the model and the second set is used for testing of the model. This partitioning corresponds to offline training of weights for the model and real-time testing of the model for determining errors in estimation of state parameter (temperature, SoC, SoH, etc.) of the DUT 104. The main benefit of such partitioning is that it allows for testing the model in an unbiased way, such as testing the model without exposing it to same data used for training.

In one example, the error criteria used for inferring model accuracy corresponds to either mean absolute error (MAE) or max error (ME). The ME provides a better estimate of the worst-case performance whereas MAE provides error in an averaged sense. Specifically, for temperature estimation, the mathematical formulation of error adopted by the temperature estimation unit 152 includes one or more of:

Maximum error:

$$ME = {max}_{k = 1 , … , K} \vert {T}_{k} - {\hat{T}}_{k} \vert . \qquad ( 22 )$$

Mean absolute error:

$$MAE = \frac{{\sum }_{k = 1}^{K} \vert {T}_{k} - {\hat{T}}_{k} \vert}{K} \qquad ( 23 )$$

For SoC estimation, the mathematical formulation of error adopted by the SoC estimation unit 154 includes one or more of:
Maximum error:

$$ME = {max}_{j = 1 , … , J} \vert {SoC}_{j} - {j}_{} \vert \qquad ( 24 )$$

Mean absolute error:

$$MAE = \frac{{\sum }_{j = 1}^{J} \vert {SoC}_{j} - {j}_{} \vert}{J} \qquad ( 25 )$$

For SoH estimation, the mathematical formulation of error adopted by the SoH estimation unit 156 includes one or more of:
Maximum error:

$$ME = {max}_{i = 1 , … , I} \vert {SoH}_{i} - {i}_{} \vert . \qquad ( 26 )$$

Mean absolute error:

$$MAE = \frac{{\sum }_{i = 1}^{I} \vert {SoH}_{i} - {i}_{} \vert}{I} \qquad ( 27 )$$

In one example, the procedure for temperature estimation methods performed by the temperature estimation unit 152 includes the application of basis functions over the impedance features (i.e., Re(Z), Im(Z), Ph(Z) and |Z|) of a chosen frequency/frequencies f_{L}. Once these impedance features are generated, the relationship between the temperature and the features is determined by performing a curve fit. Table 1 below summarizes implementation and accuracy of the various temperature estimation methods in terms of key error metrics ME and MAE tested with respect to different frequencies, impedance features and basis functions for a coin cell. In one example, simulations are performed for 50 SoC in range of [0, 1], 43 frequencies in the range from 0.02 Hz to 20 kHz and 50 temperatures in the range of −20° C. to 60° C. The errors are calculated from the test data, i.e., data which has not been used for determining the weights. It is found by comparison that the higher frequencies (f_{L}=295.5 Hz vs f_{L}=1203 Hz) are better suited for the temperature estimation and have lower errors. On the other hand, a comparison of the last three methods shows that the basis functions and frequency chosen are identical, although a higher number of impedance features reduces the error. The last method uses a combination of Re(Z), Im(Z) and Ph(Z) showcasing a maximum error of 0.05° C.

TABLE 1
Accuracy of the proposed temperature estimation
method for different basis functions

| Basis | | Mean absolute | Max. |
|---|---|---|---|
| function | Impedance features (X) | error | Error |
| (B(x)) | @ 50% SoC | [° C.] | [° C.] |
| 1, X, X² | Re(Z) @ f_{L} = 295.5 Hz | 1.17 | 3.81 |
| 1, X, X² | Re(Z) @ f_{L} = 1203 Hz | 0.99 | 2.94 |
| 1, X, X^{0.5} | Re(Z) @ f_{L} = 1203 Hz | 0.87 | 2.54 |
| 1, X, X^{0.5} | Re(Z), Im(Z) @ f_{L} = | 0.20 | 0.53 |
| | 1203 Hz | | |
| 1, X, X^{0.5} | Re(Z), Im(Z), ∠Z | 0.01 | 0.05 |
| | @ f_{L} = 1203 Hz | | |

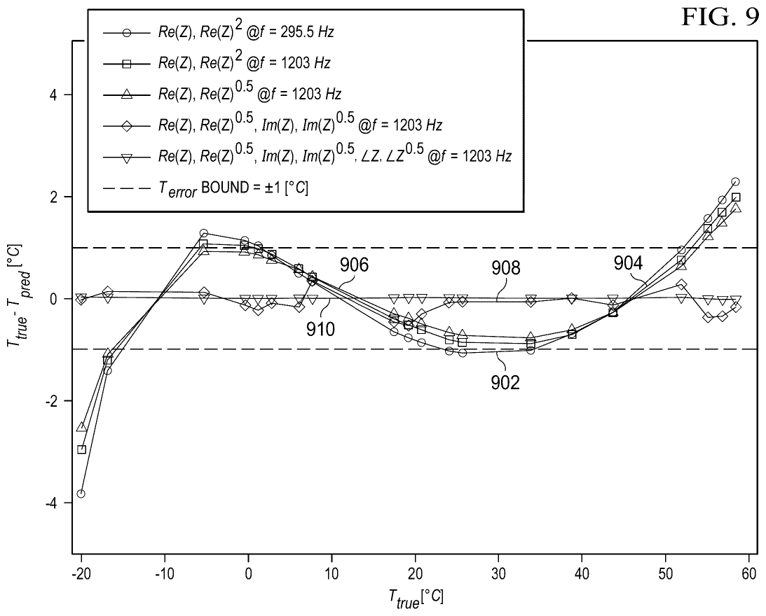

FIG. 9 shows examples of curves illustrating distribution of temperature estimation error across the temperature range for various developed methods. For the first two curves 902 and 904 shown in FIG. 9, the basis function B(x) is of the form:

$$B ( x ) = [ \begin{matrix}1 & x & {x}^{2} ]\end{matrix} \qquad ( 28 )$$

The impedance features chosen across curves 902 and 904 are at frequencies of f_{L}=295.5 Hz and f_{L}=1203 Hz, respectively. When applying the basis function (28) to the impedance features at these frequencies, it results in the following features:

$${x}_{k}^{T} [ 1 ] = 1 , {x}_{k}^{T} [ 2 ] = Re ( {Z}_{k , l} ) , {x}_{k}^{T} [ 3 ] = {Re ( {Z}_{k , l} )}^{2} \qquad ( 29 )$$

For this example, the total number of weights are N=3, which are then substituted into the Eq. (13) for solving the set of weights w*. Table 1 compares the accuracy of two of these methods for different frequency of fₗ=295.5 Hz and fₗ=1203 Hz shown by curves 902 and 904, respectively. FIG. 9 shows that for these frequencies the estimation error for certain temperature remains above the threshold of 1° C. when tested across the range of temperature between −20° C. to 60° C.

FIG. 9 shows the next three curves 906, 908, and 910 utilizing the same set of basis functions as shown here:

$$B ( x ) = [ \begin{matrix}1 & x & {x}^{0.5} ]\end{matrix} \qquad ( 30 )$$

Although, all of them have different impedance features, the curve 906 uses the Re(Z) and when the basis functions are applied to it, the resulting N=3 features are:

$${x}_{k}^{T} [ 1 ] = 1 , {x}_{k}^{T} [ 2 ] = Re ( {Z}_{k , l} ) , {x}_{k}^{T} [ 3 ] = {Re ( {Z}_{k , l} )}^{0.5} \qquad ( 31 )$$

The curve 908 uses Re(Z), Im(Z) impedance features which results in the following N=5 features:

$${x}_{k}^{T} [ 1 ] = 1 , {x}_{k}^{T} [ 2 ] = Re ( {Z}_{k , l} ) , {x}_{k}^{T} [ 3 ] = {Re ( {Z}_{k , l} )}^{0.5} \qquad ( 32 )$$

$${x}_{k}^{T} [ 4 ] = Im ( {Z}_{k , l} ) , {x}_{k}^{T} [ 5 ] = {\vert Im ( {Z}_{k , l} ) \vert}^{0.5}$$

The curve 910 uses Re(Z), Im(Z) and ∠Z impedance features which results in N=7 features:

$${x}_{k}^{T} [ 1 ] = 1 , {x}_{k}^{T} [ 2 ] = Re ( {Z}_{k , l} ) , {x}_{k}^{T} [ 3 ] = {Re ( {Z}_{k , l} )}^{0.5} {x}_{k}^{T} [ 4 ] = Im ( {Z}_{k , l} ) , {x}_{k}^{T} [ 5 ] = {\vert Im ( {Z}_{k , l} ) \vert}^{0.5} {x}_{k}^{T} [ 6 ] = ∠ ( {Z}_{k , l} ) , {x}_{k}^{T} [ 7 ] = {∠ ( {Z}_{k , l} )}^{0.5} \qquad ( 33 )$$

FIG. 9 shows the temperature estimation error for these three methods, wherein for the curve 906 the error exceeds 1° C. towards the either low or high temperatures, while for the curves 908 and 910 the error remains below 1° C. threshold. The increase in the number of impedance features from only Re(Z) in curve 906 to Re(Z), Im(Z) in 908, and Re(Z), Im(Z), ∠Z in 910 improves the accuracy.

It can be noted from Table 1 above that higher frequencies allow for more accurate temperature estimation, although higher sensitivity is required to measure the impedance increases as well. The consideration of impedance features including the Re(Z), Im(Z), ∠Z and ∥Z∥ improves the estimation as seen for the last two methods. Along with it the utilization of different sets of basis function can account for any non-linearity. Finally, these methods are not limited to uni-frequency but can consider multiple frequencies as well. The number of weights required for each of these methods is different—method 1, method 2, method 3 require N=3 weights, whereas method 4 requires N=5 weights and method 5 requires N=7 weights. These weights need to be stored in the memory 150 for the computation of the temperature, so clearly as the complexity of the method increases the number of weights that needs to be stored increases. The three final methods shown by curves 906, 908, and 910 use the frequency close to 1 kHz, of which the last two methods are able to meet the criteria with the maximum error being below the set threshold, though last method is the most computationally expensive.

In one example, the procedure for SoC estimation methods performed by the SoC estimation unit 154 includes the application of basis functions over the impedance features (i.e., Re(Z), Im(Z), Ph(Z) and ∥Z∥) of a chosen frequency/frequencies f_{L}. Once these features are generated, they learn the relationship with the SoC by performing a curve fit. Table 2 below shows an example of implementation and accuracy of the regression form for Method 1 of SoC estimation, tested with respect to different basis functions for a coin cell. It is found that the use of a higher number of basis functions gives smaller mean absolute error in SoC estimation, even though the impedance features remain the same. The last method uses a basis function as a combination of X, X⁻¹, X⁻² and log (X) applied to ∠Z@f=2.16 Hz showcasing a maximum error of 0.55.

TABLE 2
The accuracy of various regression mappings
using the Method 1 (unknown temperature)

| | Impedance | Mean Absolute | Max. Error |
|---|---|---|---|
| Basis function | Features | Error [SOC, —] | [SOC, —] |
| 1, X, X² | ∠Z @ f = | 0.072 | 0.67 |
| | 2.16 Hz | | |
| 1, X, X^{0.5} | ∠Z @ f = | 0.058 | 0.46 |
| | 2.16 Hz | | |
| 1, X, X⁻¹ | ∠Z @ f = | 0.046 | 0.30 |
| | 2.16 Hz | | |
| 1, X, X⁻¹, X⁻², log(X) | ∠Z @ f = | 0.038 | 0.55 |
| | 2.16 Hz | | |

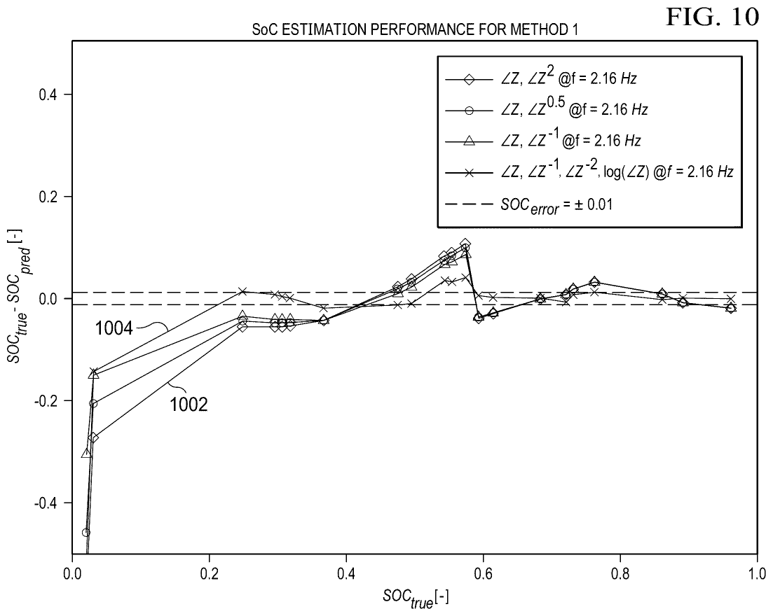

FIG. 10 shows examples of SoC estimation performance for Method 1. For Method 1, the basis function B(x) for the first regression mapping shown by curve 1002 is

$$B ( x ) = [ 1 x {x}^{2} ] \qquad ( 34 )$$

Applying the basis function B(x) to the impedance features at these frequencies results in the following feature vectors

$${x}_{j}^{T} [ 1 ] = 1 , {x}_{j}^{T} [ 2 ] = ∠ {Z}_{j , l} , {x}_{j}^{T} [ 3 ] = {( {∠Z}_{j , l} )}^{2} \qquad ( 35 )$$

Similarly, for the last regression mapping shown by curve 1004 of FIG. 10, the basis function B(x) is

$$B ( x ) = [ 1 x {x}^{- 1} {x}^{- 2} log x ] \qquad ( 36 )$$

When the basis function is applied to the impedance features, the resulting impedance feature vector is

$${x}_{j}^{T} [ 1 ] = 1 , {x}_{j}^{T} [ 2 ] = {∠Z}_{j , l} , {x}_{j}^{T} [ 3 ] = {( {∠Z}_{j , l} )}^{- 1} {x}_{j}^{T} [ 4 ] = {( {∠Z}_{j , l} )}^{- 2} {x}_{j}^{T} [ 5 ] = log ( {∠Z}_{j , l} ) \qquad ( 37 )$$

For the example of FIG. 10, the total number of weights are N=5, which are then substituted into the Eq. (17) for solving the set of weights w*. FIG. 10 shows the error in the estimation of SoC at different true SoC values, where it can be seen that the maximum error occurs close to zero state of charge. Overall, the estimation error remains above the set threshold of 0.01 in multiple regions of the estimation.

TABLE 3
The accuracy of the various regression mappings for Method 2

| Basis | Impedance | Mean Absolute | Max. Error |
|---|---|---|---|
| function (B) | Features (X) | Error in SoC [—] | in SoC [—] |
| X, X² | ∠Z @ f = 22 Hz | 0.035 | 0.178 |
| X, X^{0.5} | ∠Z @ f = 22 Hz | 0.032 | 0.148 |
| X, X^{0.5} | Re(Z), ∠Z @ f = 22 Hz | 0.010 | 0.131 |
| X, X^{0.5} | −Im(Z), ∠Z @ f = | 0.004 | 0.039 |
| | 22 Hz | | |
| X, X^{0.5} | −Im(Z), ∠Z @ f = | 0.001 | 0.015 |
| | 2.16, 22 Hz | | |

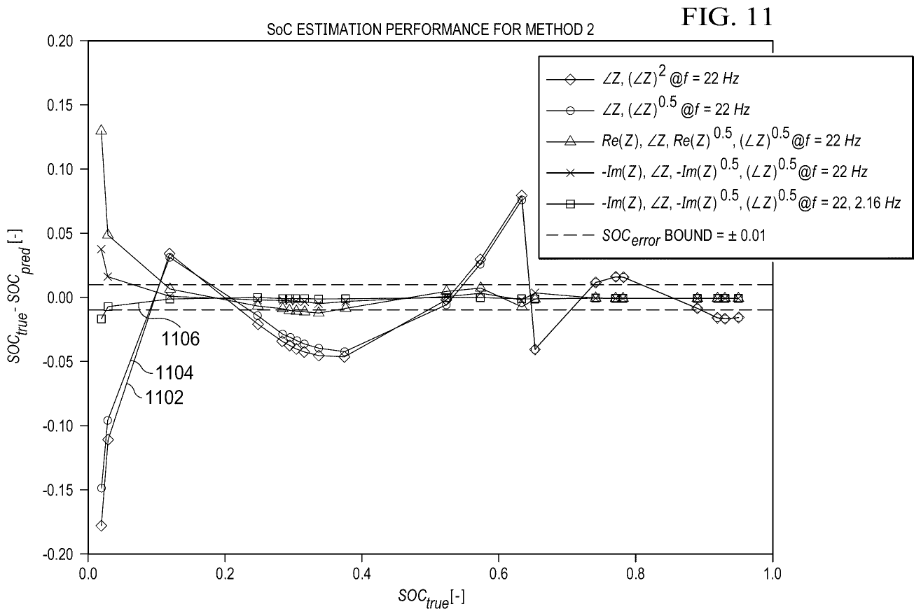

Table 3 above shows an example of implementation and accuracy of the regression mappings for Method 2 of SoC estimation for a coin cell. FIG. 11 shows examples of SoC estimation error for the various regression forms for Method 2, where the temperature of the battery cell 702 is assumed to be known and hence the corresponding weights. Following this different regression mappings are tested as shown in Table 3. Of all the regression mappings, the first one uses a basis function B(x) as

$$B ( x ) = [ 1 x {x}^{2} ] \qquad ( 38 )$$

whereas all the others use the basis function B(x) as

$$B ( x ) = [ 1 x {x}^{0.5} ] \qquad ( 39 )$$

For curve 1102 in FIG. 11, the feature vector generated when applying the basis function to them is

$${x}_{k}^{T} [ 1 ] = 1 , {x}_{k}^{T} [ 2 ] = ( {∠Z}_{k , l} ) , {x}_{k}^{T} [ 3 ] = {( {∠Z}_{k , l} )}^{2} \qquad ( 40 )$$

For curve 1104 in FIG. 11, the feature vectors generated after applying the basis function to the impedance features are

$${x}_{k}^{T} [ 1 ] = 1 , {x}_{k}^{T} [ 2 ] = ( {∠Z}_{k , l} ) , {x}_{k}^{T} [ 3 ] = {( {∠Z}_{k , l} )}^{0.5} \qquad ( 41 )$$

Similarly, the feature vectors generated for the last regression mapping shown by curve 1106 in FIG. 11 are

$${x}_{k}^{T} [ 1 ] = 1 , {x}_{k}^{T} [ 2 ] = Im ( {Z}_{k , l} ) , {x}_{k}^{T} [ 3 ] = {Im ( {Z}_{k , l} )}^{0.5} {x}_{k}^{T} [ 4 ] = ( {∠Z}_{k , l} ) , {x}_{k}^{T} [ 5 ] = {( {∠Z}_{k , l} )}^{0.5} \qquad ( 42 )$$

It is observed from Table 3 that the MAE in the estimation of SoC falls below the set threshold of 0.01 for 3^{rd} order regression mapping onwards. It can be observed that the lowest value in ME is achieved for the last regression mapping at 0.015. FIG. 11 shows the SoC estimation error for the various regression forms where it can be seen that the last mapping is able to meet the error thresholds of 0.01 for the mean error in state of charge estimations.

In summary two different methods Method 1 and Method 2 are tested for their accuracy of SoC estimation are shown in FIG. 10 and FIG. 11, respectively. It can be seen that the error is significantly higher for Method 1 where the information about the temperature is not known. The corresponding error metrics for both methods are listed in Table 2 and Table 3, respectively. For Method 1, which does not require the knowledge of temperature, it is apparent that increasing the basis function set improves the accuracy of estimation. For Method 2, it apparent that the utilization of multiple impedance features improves the accuracy of SoC estimates. Along with these observations, both methods can achieve higher accuracy when using a combination of non-linear basis functions and multiple impedance features such as the Re(Z), Im(Z), ∠Z and ∥Z∥. Finally, these methods are not limited to single frequencies but can consider multiple frequencies as well as seen in the last regression mapping in Table 2. Method 1 does not need the cell temperature information but, in return, it has lower SoC accuracy (i.e., higher SoC error). It uses a common set of weights across different temperature values and saves the cost of memory due to a smaller number of weights. In comparison, Method 2 offers higher SoC accuracy (i.e., lower SoC error) but assumes the knowledge of the temperature. There are a few things to keep in mind. First, the weights are chosen according to the temperature value. So, any error in the temperature may cause an error in the state of charge estimation. Along with it, additional memory is needed to store the weights associated with each set of temperature values.

In one example, the procedure for SoH estimation methods performed by the SoH estimation unit 156 utilizes experimental data from an open source data repository which contains the cell ageing data for a coin cell, wherein the experimental data is collected for ˜250 charge-discharge cycles in the range of frequencies from 0.02 Hz to 20 kHz.

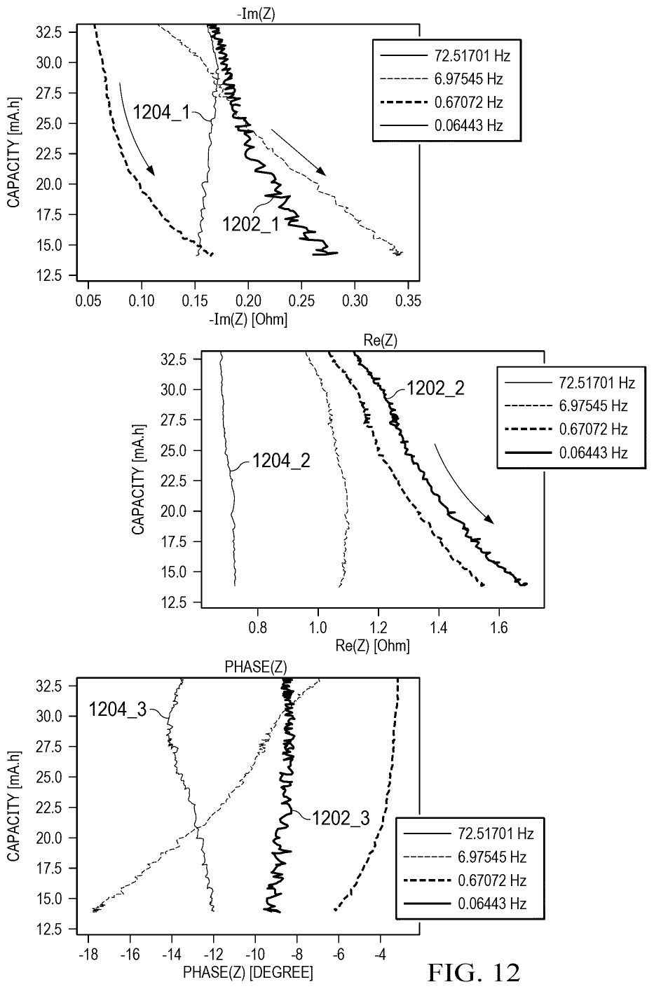

FIG. 12 shows examples of relations between the capacity, i.e., SoH of the DUT 104 as a function of three impedance features i.e. −Im(Z), Re(Z), Ph(Z) at certain frequencies, respectively. The plots shown for the few specific frequencies in FIG. 12 include 72.517 Hz, 6.975 Hz, 0.670 Hz and 0.064 Hz, respectively. The plots show that there is a clear correlation between the −Im(Z), Re(Z), and Ph(Z) vs the capacity. The capacity of the DUT 104 decreases as the imaginary and real components of the impedance increases. This information is used as a guiding point to develop a regression mapping from the impedance to the capacity which translates to SoH. It can also be seen that the accelerated ageing zone is not particularly visible because the impedance increases in proportion to the capacity fade.

For an EV battery, capacity is a good indicator of SoH of the battery because it is defined as the ratio of the capacity of aged cell to the capacity of fresh cell. The regression mapping used for estimating the SoH is

$$= {w}_{0} + {\sum }_{i} {\sum }_{j} {W}_{i , j} {B}_{j} ( {X}_{i} ( f ) ) \qquad ( 43 )$$

Here the w_{i,j} represents the weights associated with each transformation, Bⱼ represents the basis function which is applied over the impedance features Xᵢ(f) at frequency f.

Two example cases of the method are implemented here with the use of impedance features in FIG. 12 and Table 4 below. The procedure for developing such a regression mapping is shown below. The Function1 curves 1202s (e.g., 1202_1, 1202_2, and 1202_3) shown in FIG. 12 utilize the basis function B(x):

$$B ( x ) = [ 1 x {x}^{2} ] \qquad ( 44 )$$

This basis function is applied over to the impedance features Re(Z), −Im(Z), Ph(Z) @ f=6.97 Hz. After applying these basis function, the resulting transformed vector has N=9 elements:

$${x}_{k}^{T} [ 1 ] = 1 {x}_{k}^{T} [ 2 ] = Re ( Z ) {x}_{k}^{T} [ 3 ] = {Re ( Z )}^{2} {x}_{k}^{T} [ 4 ] = 1 {x}_{k}^{T} [ 5 ] = - Im ( Z ) {x}_{k}^{T} [ 6 ] = {Im ( Z )}^{2} {x}_{k}^{T} [ 7 ] = 1 {x}_{k}^{T} [ 8 ] = Ph ( Z ) {x}_{k}^{T} [ 9 ] = {Ph ( Z )}^{2} \qquad ( 45 )$$

From these impedance features, a curve fit is performed to the SoH values. The resulting curve fit results in the mean absolute error of 0.69%, maximum absolute error of 2.3% in the SoH.

Similarly, the Function2 curves 1204s (e.g., 1204_1, 1204_2, and 1204_3) are shown in FIG. 12, which utilizes the basis function B(x):

$$B ( x ) = [ 1 x {x}^{2} ] \qquad ( 46 )$$

In one example, the basis function is applied over to the impedance features Re(Z), −Im(Z), Ph(Z) @f=0.67 Hz. After applying the basis function, the resulting transformed vector has N=9 elements:

$${x}_{k}^{T} [ 1 ] = 1 {x}_{k}^{T} [ 2 ] = Re ( Z ) {x}_{k}^{T} [ 3 ] = {Re ( Z )}^{2} {x}_{k}^{T} [ 4 ] = 1 {x}_{k}^{T} [ 5 ] = - Im ( Z ) {x}_{k}^{T} [ 6 ] = {Im ( Z )}^{2} {x}_{k}^{T} [ 7 ] = 1 {x}_{k}^{T} [ 8 ] = Ph ( Z ) {x}_{k}^{T} [ 9 ] = {Ph ( Z )}^{2} \qquad ( 47 )$$

After performing a regression mapping from the impedance features to the SoH values, the resulting mean absolute error in SoH is 0.89% and a maximum absolute error of 2.4% as shown in Table 4 below. All the errors are calculated on the basis of the dataset unexposed during the training of weights.

TABLE 4
Accuracy of the proposed SoH estimation
method for different basis functions

| Basis | Impedance | Mean Absolute | Max Absolute |
|---|---|---|---|
| function | Attribute | Error in SoH | Error in SoH |
| X, X² | Re(Z), −Im(Z), ∠Z @ | 0.69% | 2.3% |
| | f = 6.97 Hz | | |
| X, X² | Re(Z), −Im(Z), ∠Z @ | 0.89% | 2.4% |
| | f = 0.67 Hz | | |

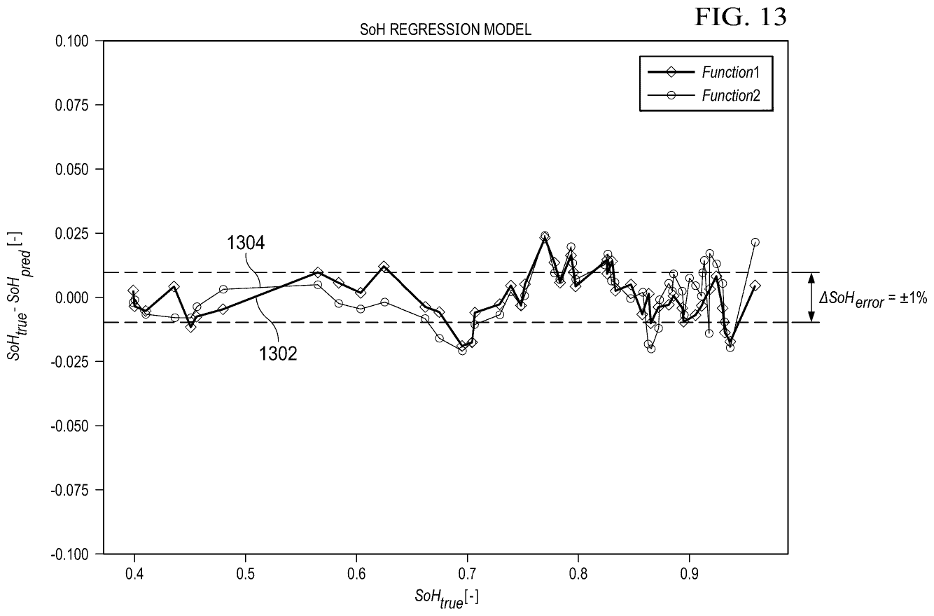

In summary, FIG. 13 shows the distribution of estimation errors across the SoH range for two feature vectors/functions Function1 1302 and Function2 1304, respectively. Table 4 above summarizes the corresponding key error metrics for each of the methods. From Table 4, it can be noted that higher frequencies allow for more accurate SoH estimation. In addition, different basis functions can be utilized to account for any non-linearity in the relationship between SoH and the impedance features. Finally, the methods described herein are not limited to a single frequency but can utilize multiple frequencies as well. The number of weights required for each method is stored in memory for the computation of SoH. As the complexity of the method increases, the number of weights increases as well.

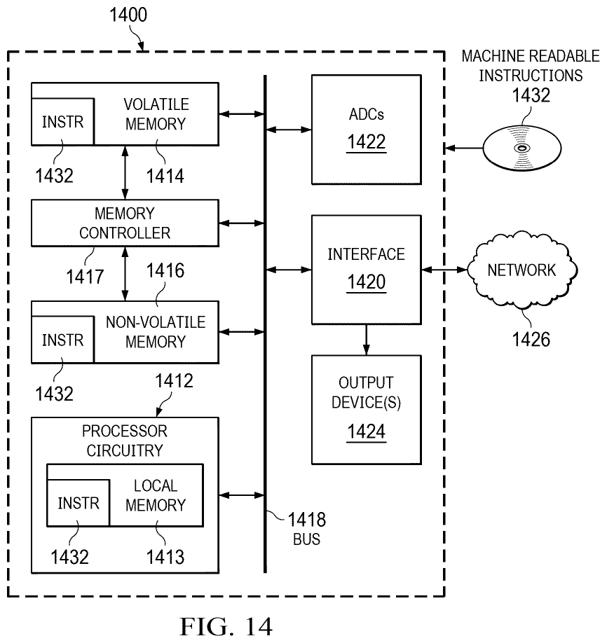

FIG. 14 is a block diagram of an example processor platform 1400 including processor circuitry structured to execute machine-readable instructions to implement the circuits and unit depicted in the examples above.

Processor platform 1400 of the illustrated example can include processor circuitry 1412. The processor circuitry 1412 of the illustrated example includes hardware. For example, processor circuitry 1412 can be implemented by one or more integrated circuits, logic circuits, FPGAs, microprocessors, Central Processing Units (CPUs), Graphical Processing Units (GPUs), Digital Signal Processors (DSPs), and/or microcontroller units (MCUs) from any desired family or manufacturer. Processor circuitry 1412 can be implemented by one or more semiconductor-based (e.g., silicon-based) devices. For example, processor circuitry 1412 can implement the processing unit(s) and control unit(s) discussed above, including the temperature estimation unit 152, the SoC estimation unit 154, and the SoH estimation unit 156, and perform the computations described in the aforementioned equations and the methods described in FIGS. 2 and 8.

Processor circuitry 1412 of the illustrated example can include a local memory 1413 (e.g., a cache, registers, etc.). Processor circuitry 1412 of the illustrated example is in communication with a computer-readable storage device such as a main memory including a volatile memory 1414 and a non-volatile memory 1416 by a bus 1418. The volatile memory 1414 can be implemented by, for example, Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1416 may be implemented by programmable read-only memory, flash memory and/or any other desired type of non-volatile memory device. Access to the main memory 1414, 1416 of the illustrated examples can be controlled by a memory controller 1417.

The processor platform 1400 of the illustrated example also includes interface circuitry 1420 to output device(s) 1424 and with network 1426. The interface circuitry 1420 may be implemented by hardware in accordance with any type of interface standard, such as an Inter-Integrated Circuit (I2C) interface, a Serial Peripheral Interface (SPI), an Ethernet interface, a universal serial bus (USB) interface, a Bluetooth® interface, a near field communication (NFC) interface, a Peripheral Component Interconnect (PCI) interface, a Peripheral Component Interconnect Express (PCIe) interface, and/or any other proprietary interface circuitry.

In the illustrated example, one or more input ADCs 1422 are connected to bus 1418. The ADCs 1422 can convert analog signals to digital signals for processing by the processor circuitry 1412.

Machine-readable instructions 1432 can be stored in volatile memory 1414 and/or non-volatile memory 1416. Upon execution by the processor circuitry 1412, the machine-readable instructions 1432 cause the processor platform 1400 to perform any or all of the functionality described herein featured to the systems and architectures discussed above.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A method, comprising:
obtaining a set of impedance values of a first device under test (DUT) across a range of excitation frequencies for a given set of values of a particular state;
determining a relationship between the given set of values of the state and the set of impedance values;
storing data representing the relationship in a memory;
receiving a voltage signal and a current signal from a second DUT;
determining an impedance of the second DUT responsive to receiving the voltage and current signals; and
determining a value of the state of the second DUT based on the impedance and the data.

2. The method of claim 1, wherein determining the relationship between the set of values of the state and the set of impedance values includes extracting a set of impedance features from the set of impedance values and transforming the set of impedance features using one or more basis functions.

3. The method of claim 2, wherein the one or more basis functions include a linear combination of multiple basis functions.

4. The method of claim 2, wherein the one or more basis functions include a non-linear combination of multiple basis functions.

5. The method of claim 2, wherein the one or more basis functions include at least one of: a power function with a rational number power, a power function with an irrational number power, a logarithm function, or an exponential function.

6. The method of claim 2, wherein determining the relationship between the range of values of the state and the set of impedance values includes determining a relationship between the range of the values and the transformed set of impedance features using a regression operation.

7. The method of claim 2, wherein the set of impedance features include at least one of: a real part of each of the set of impedance values, an imaginary part of each of the impedance values, a magnitude of each of the set of impedance values, or a phase of each of the set of impedance values.

8. The method of claim 1, wherein the DUT includes at least one of a battery or a capacitor.

9. The method of claim 1, wherein the state includes at least one of: a temperature, a state of charge (SoC), or a state of health (SoH).

10. The method of claim 1, wherein the state is a first state, the range is a first range, and the set of impedance values is obtained from the DUT across a second set of values of a second state.

11. The method of claim 10, wherein the first state is a state of charge (SoC), and the second state is a temperature or a state of health (SoH).

12. The method of claim 10, wherein the first state is independent of the second state over a portion of the first range.

13. The method of claim 1, wherein the first DUT is the second DUT.

14. A method, comprising:
obtaining a set of voltage signals and a set of current signals from a device under test (DUT) over a range of excitation frequencies across a set of values of a particular state;
determining a set of impedance values of the DUT based on the set of voltage signals and the set of current signals;
determining a relationship between the set of values of the state and the set of impedance values; and
storing data representing the relationship in a memory.

15. The method of claim 14, wherein the DUT is a first DUT, and the method further comprises:
determining an impedance of a second DUT; and
determining a value of the state of the second DUT based on the measured impedance and the data.

16. An apparatus comprising:
a memory configurable to store a first data representing a relationship between a set of values of a state of a first device and a first impedance of the first device across a frequency range; and
a processing circuit having inputs coupled to the memory and an output, the processing circuit configurable to:
determine a second impedance of a second device across the frequency range;
receive the first data from the memory;
receive at least part of the first data responsive to determining the second impedance; and
responsive to receiving the at least part of the first data, determine a state of the second device.

17. The apparatus of claim 16, wherein the processing circuit is configurable to receive a set of voltage signals and a set of current signals from the second device across the frequency range, and determine the second impedance of the second device responsive to receiving the set of voltage signals and the set of current signals.

18. The apparatus of claim 16, wherein that first and second devices are the same device.

19. The apparatus of claim 16, wherein each of the first and the second device includes at least one of a battery or a capacitor.

20. The apparatus of claim 16, wherein the state includes at least one of: a temperature, a state of charge (SoC), or a state of health (SoH).

21. The apparatus of claim 16, wherein:
the processing circuit is configurable to determine the relationship between the set of values of the first state of the first device and the first impedance of the first device by extracting a set of impedance features from the first impedance and transforming the set of impedance features using one or more basis functions.

22. The apparatus of claim 21, wherein:
the one or more basis functions includes a linear combination of multiple basis functions.

23. The apparatus of claim 21, wherein:
the one or more basis functions includes a non-linear combination of multiple basis functions.

24. The apparatus of claim 21, wherein:
the one or more basis functions include one or more of a power function with a rational number power, a power function with an irrational number power, a logarithm function, and an exponential function.

25. The apparatus of claim 21, wherein:
the set of impedance features include at least one of: a real part of each of the set of impedance values, an imaginary part of each of the set of the impedance values, a magnitude of each of the set of impedance values, and a phase of each of the set of impedance values.

26. The apparatus of claim 21, wherein:
the processing circuit is configurable to determine the relationship between the set of values of the state of the first device and the first impedance of the first device by determining a relationship between the state of the first device and the transformed set of impedance features using a regression operation.

27. The apparatus of claim 16, wherein:
the state is a first state, the range is a first range, and the first impedance is obtained from the DUT across a second set of values of a second state.

28. The apparatus of claim 27, wherein:
the first state is a state of charge (SoC), and the second state is a temperature or a state of health (SoH).

29. The apparatus of claim 27, wherein:
the first state is independent of the second state over a portion of the first range.

30. A non-transitory computer readable medium storing instructions that, when executed by a processor circuitry, cause the processor circuitry to:
obtain a set of impedance values of a first device under test (DUT) across a range of excitation frequencies for a set of values of a particular state;
determine a relationship between the set of values of the state and the set of impedance values;
store data representing the relationship in a memory;
receive a voltage signal and a current signal from a second DUT;
determine an impedance of the second DUT based on the voltage and current signals; and
determine a value of the state of the DUT based on the impedance and the data.
